(19) United States
(12) Patent Application Publication
(10) Pub. No.: US 2006/0133169 A1
(43) Pub. Date: Jun. 22, 2006

(54) Address comparator of semiconductor memory device

(75) Inventor: Seok Joo Lee, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (JP)

(21) Appl. No.: 11/182,213

(22) Filed: Jul. 15, 2005

(30) Foreign Application Priority Data
Dec. 21, 2004 (KR) 2004-109322

(51) Int. Cl. G11C 7/00

(52) U.S. Cl. 365/205

(57) ABSTRACT

Disclosed is an address comparator configured to flow a current only for an initial short time, but not at other times, such as when an address is input thereto for a repair operation. The address comparator includes a plurality of unit address comparators comparing addresses received for the repair operation, a PMOS transistor turned on for a short time, an NMOS transistor controlling a current flow through the plurality of unit address comparators , and a PMOS transistor turned off when the plurality of unit comparators allows the current flow, and turned on when the plurality of unit comparators does not allow the current flow.

### BACKGROUND

1. Field of the Disclosure

The present disclosure relates to semiconductor memory devices and, more specifically, to an address comparator with decreased current consumption.

2. Discussion of Related Technology

A memory chip typically has a storage space that is substituted for a normal storage space when the normal storage space is defective, for which a redundancy circuit is provided to the memory chip. There are various techniques for storing information about a defective memory address to be substituted. One technique for storing redundancy information is a fuse cutting method using laser option. An operation substituting a defective cell with a spare cell is referred to as a repairing operation. In such cases, an address comparison step precedes the repairing operation.

FIG. 1 is a circuit diagram illustrating a conventional address comparator, and FIG. 2 is a circuit diagram illustrating an operation of the address comparator shown in FIG. 1. Referring to FIG. 1, a conventional address comparator includes fuses F0-Fn, NMOS transistors MN and MN0-MNn, a PMOS transistor MP1, inverters IV1-IV3, a N0R gate NR1, and a capacitor CP1, for carrying out address comparison with cutting fuses oppositely arranged against a corresponding address.

In operation, and with reference to FIG. 2, a repairing operation is accomplished by cutting the fuse F0 connected to a power source voltage VCC and cutting the fuses F1-Fn in suit with the arrangement of addresses A0-An and /A0-/An.

As an example, when the address A1:A0=10 is required to be repaired, the fuses F1 and F4 are cut off. Then, the NMOS transistors MN2 and MN3 are turned on to flow a current. Thereby, a node RF becomes logical low, while a repair signal RFEN becomes logical high.

During this, as the PMOS transistor MP1 continues to be turned on, it may be problematic to maintain a current flow if the address A1 and A0 are activated a long time. If the PMOS transistor MP1 is decreased in size in order to reduce the current flow, it may cause the response speed of the repair signal RFEN to be lower.

### SUMMARY OF THE DISCLOSURE

Disclosed herein is an address comparator configured to allow current flow only for an initial short time period, but not at other times, even when an address is input thereto for a repair operation.

In accordance with one aspect of the disclosure, an address comparator includes a plurality of unit address comparators connected between first and second nodes to compare addresses input for a repairing operation, a first precharging circuit to precharge the first node for a short time, a first discharging circuit to control a current flow through the plurality of unit address comparators connected between the first and second nodes, and a second precharging circuit inactivated when the current flow is allowed and to precharge the first node when the current flow is not allowed.

In one embodiment, the address comparator further includes an enable signal generator configured to generate an enable signal for operating the plurality of unit address comparators.

### BRIEF DESCRIPTION OF THE DRAWINGS

The accompanying drawings are included to provide further details regarding the disclosed address comparator, and are incorporated in and constitute a part of this specification. The drawings illustrate exemplary embodiments of the disclosed address comparator and, together with the description, also serve to set forth principles, features and aspects of the disclosed address comparator. In the drawings:

FIG. 1 is a circuit diagram illustrating a conventional address comparator;

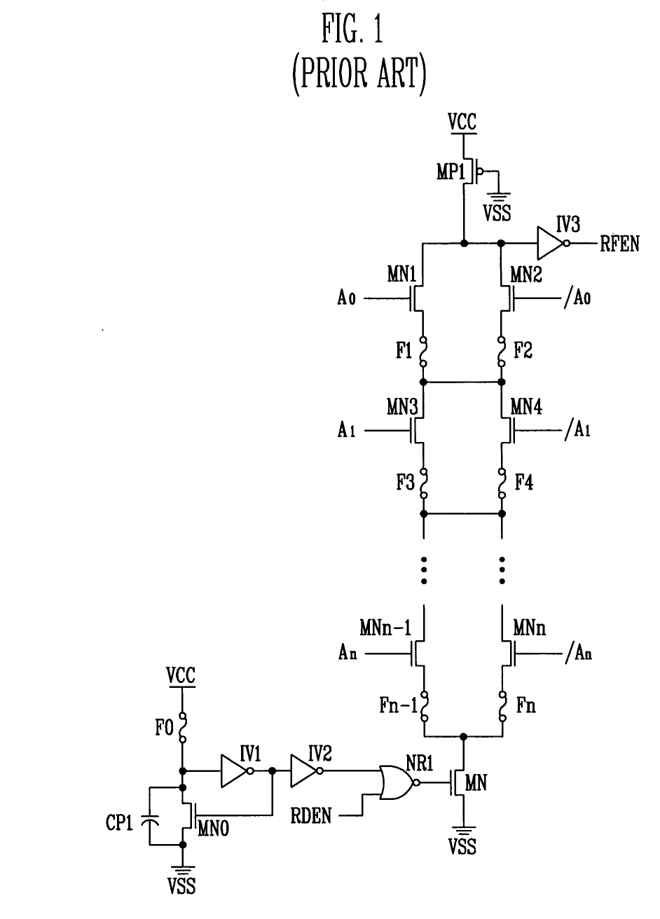

FIG. 2 is a circuit diagram illustrating an operation of the address comparator shown in FIG. 1;

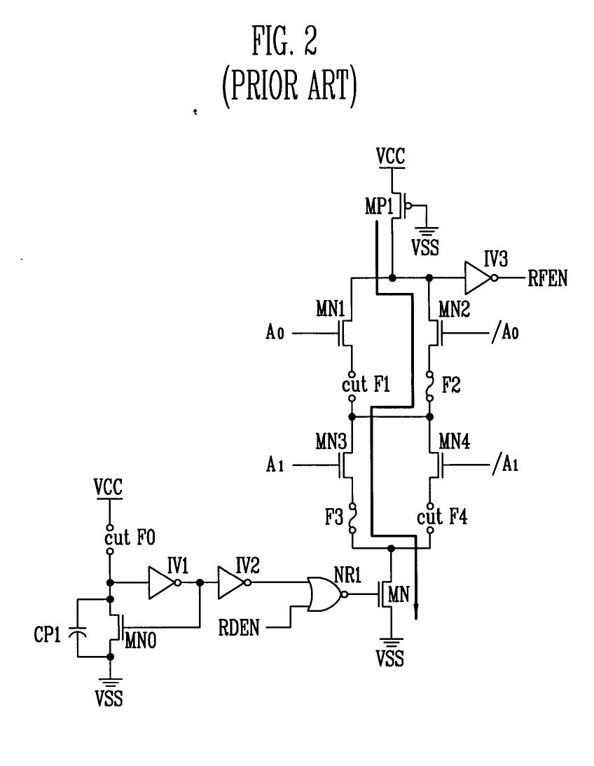

FIG. 3 is a circuit diagram illustrating an address comparator in accordance with one embodiment of the disclosure;

FIG. 4 is a circuit diagram illustrating an operation of the address comparator shown in FIG. 3; and

FIG. 5 is a timing diagram illustrating the operation of the address comparator shown in FIG. 3.

### DETAILED DESCRIPTION OF PREFERRED EMBODIMENTS

A number of embodiments of the disclosed address comparator will be described below in more detail with reference to the accompanying drawings. The disclosed address comparator may, however, be embodied in different forms and should not be considered to be limited to the embodiments set forth herein. Rather, the exemplary nature of these embodiments will fully convey the scope of the appended claims to those skilled in the art. In the drawings, the thickness of layers and regions may be exaggerated for clarity. Further, like numerals refer to like elements throughout the specification.

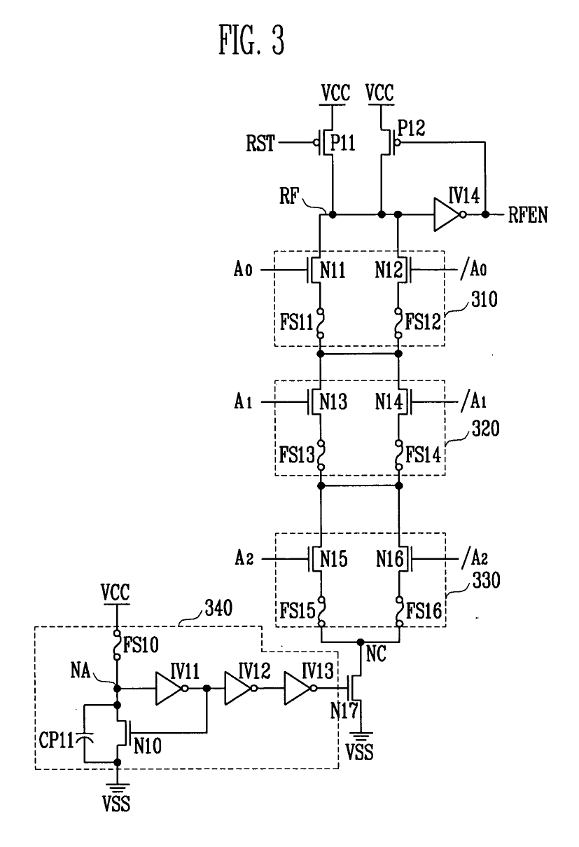

FIG. 3 is a circuit diagram illustrating an address comparator in accordance with one embodiment of the disclosed address comparator that includes unit address comparators 310, 320 and 330, an enable signal generator 340, PMOS transistors P11 and P12, an NMOS transistor N17, and an inverter IV14. The PMOS transistor P11 has a terminal connected to a power source voltage VCC and another terminal connected to a node RF, the transistor P12 being turned on or off in response to a reset signal RST applied to its gate. The PMOS transistor P11 is turned on to precharge the node RF only when the reset signal RST is applied with a logical low pulse, which may have a short duration to minimize or decrease current consumption. The inverter IV14 inverses a signal of the node RF and outputs a repair signal RFEN.

The PMOS transistor P12 has a terminal connected to a power source voltage VCC and another terminal connected to the node RF, the transistor P12 being turned on or off in response to the output signal of the inverter IV14 applied to its gate. The PMOS transistor P12 is turned on to precharge the node RF when the node RF is set to a logical high, and turned off when the node RF is at a logical low. In other words, if the unit address comparators 320, 330 and 340 allow a current flow, the node RF becomes logical low to turn the PMOS transistor P12 off.

The unit address comparator 310 includes NMOS transistors N11 and N12, and fuses FS11 and FS12. The NMOS transistor N11 has a terminal connected to the node RF and another terminal connected to an end of the fuse FS11, the transistor N11 receiving the address bit A0 through to its gate. The NMOS transistor N12 has a terminal connected to the node RF and another terminal connected to an end of the fuse FS12, the transistor N12 receiving the address bit/A0 through to its gate. The fuse FS11 is connected between the NMOS transistors N11 and N13, while the fuse FS12 is connected between the NMOS transistors N12 and N14. The other ends of the fuses FS11 and FS12 connected to the transistors N13 & N14 are also connected to each other.

The unit address comparator 320 includes the NMOS transistors N13 and N14, and fuses FS13 and FS14. The NMOS transistor N13 is connected between the fuses FS11 and FS13, and receives the address bit A1 through its gate. The NMOS transistor N14 is connected between the fuses FS12 and FS14, and receives the address bit/A1 through its gate. The fuse FS13 is connected between the NMOS transistors N13 and N15. The fuse FS14 is connected between the NMOS transistors N14 and N16. Ends of the fuses FS13 and FS14 connected to the transistors N15 and N16 are also connected to each other.

The unit address comparator 330 includes the NMOS transistors N15 and N16, and fuses FS15 and FS16. The NMOS transistor N15 is connected between the fuses FS13 and FS15, and receives the address bit A2 through its gate. The NMOS transistor N16 is connected between the fuses FS14 and FS16, and receives the address bit/A2 through its gate. The fuse FS15 is connected between the NMOS transistor N15 and anode NC. The fuse FS16 is connected between the NMOS transistor N16 and the node NC.

The enable signal generator 340 is provided to activate the unit address comparators 310, 320 and 330, and includes a fuse FS10, a capacitor CP11, an NMOS transistor N10, and inverters IV11, IV12 and IV13. The fuse FS10 is connected to the power source voltage VCC at one end and connected to a node NA at another end. The inverter IV11 inverts a signal of the node NA. The NMOS transistor N10 is connected to the node NA through one terminal thereof and connected to the ground voltage VSS through another terminal thereof, the transistor N10 receiving an output signal of the inverter IV11 through it gate. The capacitor CP11 is connected between the node NA and the ground voltage VSS, the capacitor CP11 being coupled with the NMOS transistor N10 in parallel. The inverters IV12 and IV1 transfer the output signal of the inverter IV11 with a delay.

An NMOS transistor N17 is connected to the node NC through one terminal thereof and connected to the ground voltage VSS through another terminal thereof, the transistor N17 being turned on or off in response to an output signal of the enable signal generator 340 applied to its gate. The NMOS transistor N17 is turned on to enable discharging when the output signal of the enable signal generator 340 is at a logical high, so that the node NC is connected to the ground voltage VSS and the unit address comparators 310, 320 and 330 can be conductive.

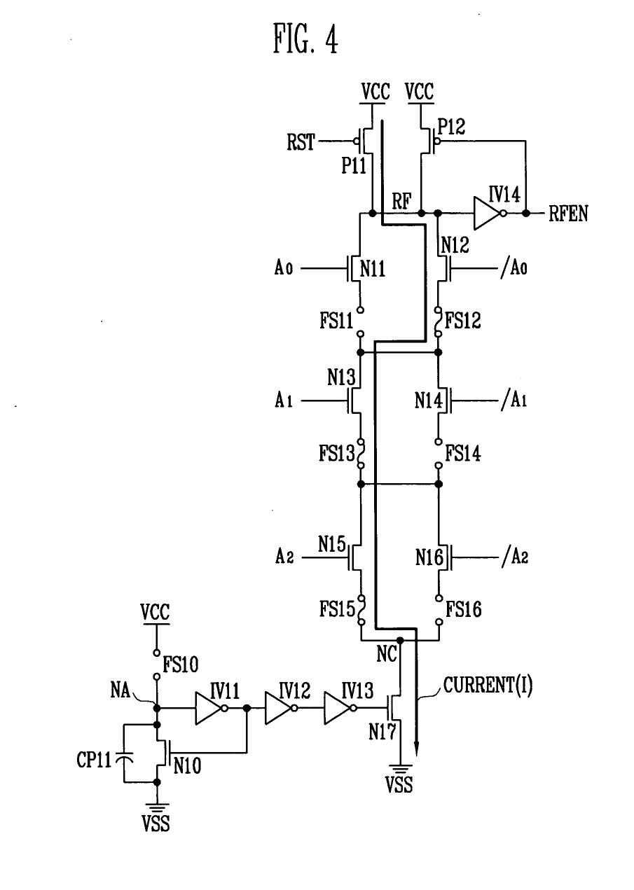

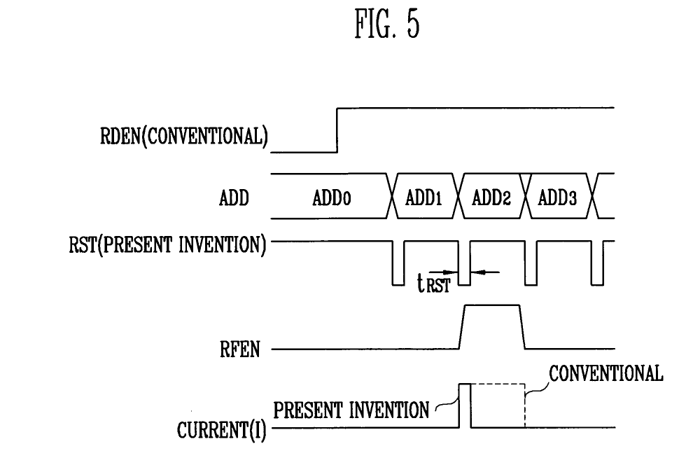

FIG. 4 is a circuit diagram illustrating an operation of the address comparator shown in FIG. 3, and FIG. 5 is a timing diagram illustrating the operation of the address comparator shown in FIG. 3. Specifically, an operation of comparing addresses in conjunction is now described in connection with. FIGS. 4 and 5.

First, in order to activate the redundancy circuit (not shown) for utilization, i.e., in order to initiate the repairing operation, the fuse FS10 connected to the power source voltage VCC is cut, along with those fuses of fuses FS11, FS12, FS13, FS14, FS15 and FS16 suitable for the arrangement of the address bits A0-A2 and /A1-/A2. Cutting the fuse FS10 causes the NMOS transistor N17 to be activated.

For instance, in the case of repairing the address A2:A1:A1=110, the fuses FS11, FS14, and FS16 are cut off as illustrated in FIG. 4. In this case, if the reset signal RST is applied to the transistor P11 as a low pulse for a time to take a node RF to a high level as shown in FIG. 5, the PMOS transistor P11 is turned on and the node RF goes to logical low. But if the address bits A2, A1, and A0 are supplied with 110 and the NMOS transistor N17 is being turned on, the NMOS transistors N12, N13, and N15 are turned on to flow a current I and the repair signal RFEN becomes logical high. Thus, the current I flows only when the reset signal RST remains low for a short time tᵣₛₜ, as shown in FIG. 5, and no current flows thereafter. Thus, the time tᵣₛₜ may be a time period selected or predetermined to minimize or decrease current consumption. As a further result, there is no need to control the address comparator on or off with a signal RDEN, and instead the reset signal RST is input with a low pulse at the time when an address for repairing is introduced thereto. Unless the address for repairing is introduced thereto, i.e., if the address A2:A1:A0=100 is input thereto, there is no flow of the current I and thereby the node RF is floated. The node RF becomes logical high when the reset signal RST is being on logical low at the initial state, and retains the logical high, without being floated, by a turn-on state of the PMOS transistor P12 even if the PMOS transistor P11 is turned off.

As described above, the disclosed address comparator is advantageous for reducing current consumption in a semiconductor memory device by limiting current flow through an address comparator to an initial short time even if an address for repairing is introduced therein.

Moreover, the address comparator disclosed herein is effective in reducing current consumption for a chip in need of low current during a standby mode or, more generally, for a low-power chip.

Although the disclosed address comparator has been described in connection with the embodiments illustrated in the accompanying drawings, it shall be understood that the scope of the disclosed address comparator is not limited thereto. It will be apparent to those skilled in the art that various substitutions, modifications and changes may be made thereto without departing from the scope and spirit of the invention.

What is claimed is:

1. An address comparator of a semiconductor memory device, comprising:
a plurality of unit address comparators connected between first and second nodes to compare addresses input for a repairing operation;
a first precharging circuit to precharge the first node for a time to take the first node to a high level;
a first discharging circuit to control a current flow through the plurality of unit address comparators connected between the first and second nodes; and
a second precharging circuit inactivated when the current flow is allowed and to precharge the first node when the current flow is not allowed.

2. The address comparator as set forth in claim 1, wherein the first precharging circuit comprises a MOS transistor that is turned on by a reset signal with a short pulse and precharges the first node up to logical high by means of a power source voltage.

3. The address comparator as set forth in claim 1, wherein the second precharging circuit comprises a MOS transistor that is turned on by a signal inverted from a signal of the first node and precharges the first node up to logical high by means of a power source voltage.

4. The address comparator as set forth in claim 1, further comprising an enable signal generator to generate an enable signal for operating the plurality of unit address comparators.

5. The address comparator as set forth in claim 4, wherein the first discharging circuit activates the plurality of unit address comparators in response to the enable signal generated by the enable signal generator.

6. The address comparator as set forth in claim 4, wherein the enable signal generator comprises:
a fuse connected between a power source voltage and a third node;
first through third inverters temporarily storing and outputting a signal of the third node;
a capacitor coupled between the third node and a ground voltage; and
an NMOS transistor connected between the third node and the ground voltage to receive an output signal from the first inverter through a gate of the NMOS transistor.

7. The address comparator as set forth in claim 6, wherein the first discharging circuit is enabled when the fuse is cut off.
